(19) United States
(12) Patent Application Publication
(10) Pub. No.: US 2016/0336370 A1
(43) Pub. Date: Nov. 17, 2016

(54) FOCAL PLANE ARRAYS WITH BACKSIDE CONTACTS

(71) Applicant: Sensors Unlimited, Inc., Princeton, NJ (US)

(72) Inventor: Peter Dixon, Lawrenceville, NJ (US)

(21) Appl. No.: 14/708,900

(22) Filed: May 11, 2015

(51) Int. Cl. H01L 27/146; H04N 5/378

(52) U.S. Cl. CPC H01L 27/14636; H01L 27/14649; H04N 5/378

(57) ABSTRACT

A package assembly includes a package body and a focal plane array (FPA) within the package body. The FPA includes a read out integrated circuit (ROIC) having a circuit side. A photodiode array (PDA) defines an optical axis and has a backside electrically connected to the circuit side of the ROIC. A plurality of conductive through-vias extend from the circuit side of the ROIC through to input/output (I/O) bondpads on the backside of the ROIC. A window is operatively connected between the FPA and the package body.

### STATEMENT REGARDING FEDERALLY SPONSORED RESEARCH OR DEVELOPMENT

This invention was made with government support under contract number HR0011-13-C-0068 awarded by DARPA. The government has certain rights in the invention.

### BACKGROUND OF THE INVENTION

1. Field of the Invention

The present disclosure relates to focal arrays, and more particularly to infrared focal plane arrays and packaging therefor.

2. Description of Related Art

A variety of devices and methods are known in the art for infrared focal plane array (FPA) image sensors. Traditional FPA image sensors include a photodiode array (PDA) packaged with a read out integrated circuit (ROIC). The package containing the FPA is generally electrically coupled to the topside of the ROIC via bond wires and bond pads such that circuitry on the ROIC can be electrically accessed.

Such conventional methods and systems have generally been considered satisfactory for their intended purpose. However, there is still a need in the art for improved FPA devices and packaging therefor. The present disclosure provides a solution for this need.

### SUMMARY OF THE INVENTION

A focal plane array (FPA) includes a read out integrated circuit (ROIC) having a circuit side. A photodiode array (PDA) defines an optical axis and has a backside electrically connected to the circuit side of the ROIC. A plurality of conductive through-vias extend from the circuit side of the ROIC through to input/output (I/O) bondpads on the backside of the ROIC, e.g., for the purpose of making the I/O bondpads accessible from the back-side of the ROIC die to facilitate surface mount packaging configurations not currently possible with traditional top-side wirebond pad schemes.

The backside of the PDA can include pixel circuitry, and the topside of the PDA can be free from wire bond connections. In addition to or in lieu of the topside of the PDA being free from wire bond connections, the circuit side of the ROIC can be free from wire bond connections. The FPA can include a window directly abutting the topside of the PDA. A perimeter of the ROIC in a plane perpendicular to the optical axis can be equal to a perimeter of the PDA in another plane perpendicular to the optical axis. Optionally, the circuit side of the ROIC can be covered entirely by the PDA. The conductive through-vias can extend in a direction parallel to the optical axis.

In another aspect, a package assembly includes a package body and a FPA within the package body. The FPA is similar to the FPA described above. A window is operatively connected between the FPA and the package body. The window can be defined in an opening of the package body. The package body can be electrically connected to the conductive through-vias on the backside of the ROIC. A perimeter of the ROIC in a plane perpendicular to the optical axis can be equal to perimeters of the PDA and the window in other respective planes perpendicular to the optical axis.

These and other features of the systems and methods of the subject disclosure will become more readily apparent to those skilled in the art from the following detailed description of the preferred embodiments taken in conjunction with the drawings.

### BRIEF DESCRIPTION OF THE DRAWINGS

So that those skilled in the art to which the subject disclosure appertains will readily understand how to make and use the devices and methods of the subject disclosure without undue experimentation, preferred embodiments thereof will be described in detail herein below with reference to certain figures, wherein:

FIG. 1 is a schematic cross-sectional view of an exemplary embodiment of a package assembly constructed in accordance with the present disclosure, showing a focal plane array (FPA); and

FIG. 2 is a schematic exploded cross-sectional view of the FPA of FIG. 1, showing the photo diode array (PDA) and the read out integrated circuit (ROIC).

### DETAILED DESCRIPTION OF THE PREFERRED EMBODIMENTS

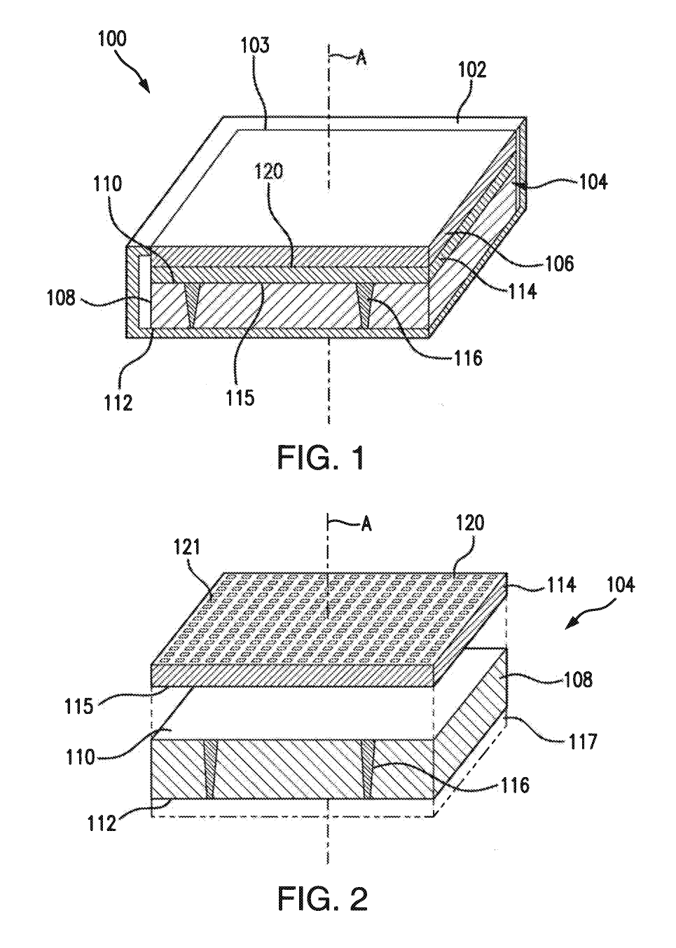

Reference will now be made to the drawings wherein like reference numerals identify similar structural features or aspects of the subject disclosure. For purposes of explanation and illustration, and not limitation, a partial view of an exemplary embodiment of a package assembly in accordance with the disclosure is shown in FIG. 1 and is designated generally by reference character 100. Other embodiments of package assemblies in accordance with the disclosure, or aspects thereof, are provided in FIG. 2, as will be described. The systems and methods described herein can be used to reduce overall package size and focal plane array footprint, while increasing ease of wafer-to-wafer bonding.

The ROIC I/O contact pads are typically physically located in the surrounding peripheral edge of the ROIC. This is to facilitate, for example, placement of the infrared FPA (IRFPA), e.g., a PDA or sensor chip array, or other image sensor with a plurality of pixels, in an interior two-dimensional array. These edge contact I/O pads are the functional electrical connections, made for power, ground, clocks, analog and/or digital signals, or the like. The ROIC interfaces with camera electronics, or the like, by these connections typically through wirebond contacts made from the ROIC I/O pads to some printed circuit board assembly (PCBA), ceramic substrate, or the like, designed for said purpose.

The systems and methods disclosed herein make application of insulated through vias at these I/O pad locations, thus facilitating reduced package area by use of surface mount (using back-side contacts), reduction or elimination of wirebonds, improved optical path by reduced lens backworking distance, improved path to chipscale packaging, improved design freedom with respect to I/O layout and placement within the ROIC die, as well as improved design freedom with respect to PDA size constraints typically brought about by the need to accommodate top-side electrical connections.

As shown in FIG. 1, a package assembly 100 includes a package body 102 and a focal plane array (FPA) 104 within package body 102. Package body 102 can be any suitable type of package such as a ceramic, printed circuit board (PCB), or the like. A window 106 is operatively connected to FPA 104 and package body 102. Window 106 is defined in an opening 103 of package body 102. FPA 104 includes a read out integrated circuit (ROIC) 108 having a circuit side 110 and a backside 112 opposite of circuit side 110. A photodiode array (PDA) 114 defines an optical axis A and has a backside 115 electrically connected to circuit side 110 of ROIC 108, e.g, with bump bonds or the like. Window 106 directly abuts topside 120 of PDA 114. Those skilled in the art will readily appreciate that by bonding window 106 directly to PDA 114 image quality can be improved due to the reduced reflections, e.g. those reflections typically caused by metal traces and/or wires on the topside 120 of PDA 114. It is contemplated that FPA 104 can be an infrared FPA and that PDA 114 can be an InGaAs PDA.

With continued reference to FIG. 1, a plurality of conductive through-vias 116 extend from circuit side 110 of ROIC 108 through to the backside 112 in a direction parallel to optical axis A, e.g., for the purpose of making the input/output (I/O) bondpads on the backside of ROIC 108 accessible from the backside 112 of the ROIC die to facilitate surface mount packaging configurations not currently possible with traditional top-side wirebond pad schemes. The I/O bondpads of ROIC 108 are located where conductive through-vias 116 meet backside 112, and can be any suitable type of backside metal contacts or the like, e.g., blind insulated vias exposed by subsequent processes. Package body 102 is electrically connected to ROIC 108 through the conductive through-vias 116 at backside 112 of ROIC 108. Those skilled in the art will readily appreciate that any other suitable back-side via connections can be used without departing from the scope of this disclosure, such as ball grid arrays (BGA), anisotropically conductive film (ACF), or z-axis film.

Respective perimeters of ROIC 108, PDA 114 and window 106 in respective planes perpendicular to the optical axis A are equal one another. Those skilled in the art will readily appreciate that with backside contacts by way of through-vias 116, wire bond pads on circuit side 110 of ROIC 108 are not required. This enables PDA 114 to be sized up to the extent of ROIC 108, facilitating wafer-to-wafer bonding.

As shown in FIG. 2, backside 115 of PDA 114 includes pixel circuitry 121, and topside 120 is free from wire bond connections. In addition to or in lieu of topside 120 being free from wire bond connections, circuit side 110 of ROIC 108 can be free from wire bond connections. It is therefore an option for ROIC 108 to be covered entirely by PDA 114. Those skilled in the art will readily appreciate that it is also possible for the ROIC 108 to be covered less than entirely by the PDA 114 without departing from the scope of this disclosure.

During manufacture, a portion 117 of backside 112 of ROIC 108, indicated schematically by dashed lines, is ground away to expose the conductive through-vias 116 before assembling into package 100, as shown in FIG. 1. Those skilled in the art will also readily appreciate that artifacts such as light scattering are more easily mitigated without concern for topside electrical contacts, for example, by painting the edges of the PDA. It is also contemplated that the backside contacts between PDA 114 and ROIC 108 permit ROIC 108 electronics of circuit side 110 to be buried within FPA 104, therein protecting the electronics from radiation and increasing reliability and countermeasure resilience.

By removing all topside in-put/out-put considerations on ROIC 108 and PDA 114, fewer challenges are placed in the optical path, thus the optics can be designed with fewer limitations. Such challenges in traditional configurations include wirebonds and required mechanical clearances, and any top-side electrical contact would necessarily prevent optical elements from being butted to the surface of the FPA without incorporating electrical traces in those optical elements. Thus, common, traditional package design includes some clearance distance between the FPA and the optical mount, thus adding back-working distance, and making the total package, including lens diameter, necessarily larger than would be with a reduced backworking distance. Other optical considerations include reflections or scattering sources for light, which are presented by the mechanical considerations mentioned above. Those skilled in the art will readily appreciate that optionally some topside contacts can still be present on ROICs in accordance with this disclosure, e.g., for testing purposes or the like.

A method for forming a FPA, e.g. FPA 104, includes forming a plurality of conductive through-vias, e.g. conductive through-vias 116, extending through a ROIC, e.g. ROIC 108, starting from a circuit side, e.g. circuit side 110. The method includes grinding a portion, e.g. portion 117, of the ROIC from a backside, e.g. backside 112, to expose the conductive through-vias. Those skilled in the art will readily appreciate that the method can include electrically connecting circuitry on a circuit side, e.g. circuit side 110, of the ROIC to a PDA, e.g. PDA 114. It is also contemplated that the method can include electrically connecting the through-vias from the backside of ROIC 108 to a package, e.g. package 100, e.g., with bump bonds.

The methods and systems of the present disclosure, as described above and shown in the drawings, provide for focal plane arrays and packaging therefor with superior properties including reduced size, increased manufacturability, and increased mitigation ability for artifacts such as light scattering. While the apparatus and methods of the subject disclosure have been shown and described with reference to preferred embodiments, those skilled in the art will readily appreciate that changes and/or modifications may be made thereto without departing from the scope of the subject disclosure.

What is claimed is:

1. A focal plane array (FPA) comprising:
a read out integrated circuit (ROIC) having a circuit side;
a photodiode array (PDA) defining an optical axis having a backside electrically connected to the circuit side of the ROIC; and
a plurality of conductive through-vias extending from the circuit side of the ROIC through to I/O bondpads on the backside of the ROIC.

2. A focal plane array as recited in claim 1, wherein the backside of the PDA includes pixel circuitry.

3. A focal plane array as recited in claim 1, wherein a topside of the PDA is free from wire bond connections.

4. A focal plane array as recited in claim 1, further comprising a window directly abutting a topside of the PDA.

5. A focal plane array as recited in claim 1, wherein a perimeter of the ROIC in a plane perpendicular to the optical axis is equal to a perimeter of the PDA in another plane perpendicular to the optical axis.

6. A focal plane array as recited in claim 1, wherein the circuit side of the ROIC is covered entirely by the PDA.

7. A focal plane array as recited in claim 1, wherein the conductive through-vias extend in a direction parallel to the optical axis.

8. A package assembly comprising:
a package body;
a focal plane array (FPA) within the package body including:
a read out integrated circuit (ROIC) having a circuit side;
a photodiode array (PDA) defining an optical axis having a backside electrically connected to the circuit side of the ROIC; and
a plurality of conductive through-vias extending from the circuit side of the ROIC through to a backside of the ROIC; and
a window operatively connected between the FPA and the package body.

9. A package assembly as recited in claim 8, wherein the backside of the PDA includes pixel circuitry.

10. A package assembly as recited in claim 8, wherein a topside of the PDA and/or the circuit side of the ROIC is free from wire bond connections.

11. A package assembly as recited in claim 8, wherein the window directly abuts a topside of the PDA.

12. A package assembly as recited in claim 8, wherein the window is defined in an opening of the package body.

13. A package assembly as recited in claim 8, wherein the package body is electrically connected to the conductive through-vias on the backside of the ROIC.

14. A package assembly as recited in claim 8, wherein a perimeter of the ROIC in a plane perpendicular to the optical axis is equal to perimeters of the PDA and the window in other respective planes perpendicular to the optical axis.

15. A package assembly as recited in claim 8, wherein the conductive through-vias extend in a direction parallel to the optical axis.
